(19) United States
(12) Patent Application Publication
(10) Pub. No.: US 2013/0056049 A1
(43) Pub. Date: Mar. 7, 2013

(54) MULTILAYER MATERIAL, ENCAPSULANT FOR A SOLAR CELL, INTERLAYER FOR SAFETY (LAMINATED) GLASS, SOLAR CELL MODULE, AND SAFETY (LAMINATED) GLASS

(71) Applicants: Kazuyuki Nakata, Minato-ku (JP); Koichi Nishijima, Ichihara-shi (JP); Yasuki Shibata, Ichihara-shi (JP); Yoshitaka Hironaka, Ichihara-shi (JP)

(72) Inventors: Kazuyuki Nakata, Minato-ku (JP); Koichi Nishijima, Ichihara-shi (JP); Yasuki Shibata, Ichihara-shi (JP); Yoshitaka Hironaka, Ichihara-shi (JP)

(73) Assignee: DU PONT-MITSUI POLYCHEMICALS CO., LTD., Minato-ku, Tokyo (JP)

(21) Appl. No.: 13/697,391

(22) PCT Filed: May 12, 2011
(86) PCT No.: PCT/JP2011/061002

§ 371 Date: Nov. 12, 2012

(30) Foreign Application Priority Data
May 13, 2010 (JP) 2010-111366
Sep. 17, 2010 (JP) 2010-209356

(51) Int. Cl. B32B 7/02; B32B 9/04; B32B 17/10; H01L 31/0203

(52) U.S. Cl. 136/251; 136/259; 428/447; 428/220; 428/213; 428/429

(57) ABSTRACT

The present invention provides a multilayer material which has a layer (A) that contains a silane coupling agent and an ethylene type zinc ionomer, and a layer (B) that contains at least one of an ethylene type magnesium ionomer or an ethylene type sodium ionomer. The multilayer material is suitable for use as an encapsulant for a solar cell or an interlayer for safety (laminated) glass. It is preferable that the multilayer material contains at least two of the layer (A) and at least one of the layer (B) and has a multilayered structure in which the layer (B) is interposed between the two of the layer (A).

### TECHNICAL FIELD

The present invention relates to a multilayer material, an encapsulant for a solar cell, an interlayer for safety glass (laminated glass), a solar cell module, and safety glass (laminated glass).

### BACKGROUND ART

Hydroelectric power generation, wind power generation, photovoltaic power generation and the like, which can be used to attempt to reduce carbon dioxide or improve other environmental problems by using inexhaustible natural energy, have received much attention. Among these, photovoltaic power generation has seen a remarkable improvement in performance such as the power generation efficiency of solar cell modules, and an ongoing decrease in price, and national and local governments have worked on projects to promote the introduction of residential photovoltaic power generation systems. Thus, in recent years, the spread of photovoltaic power generation systems has advanced considerably.

By photovoltaic power generation, solar light energy is converted directly to electric energy using a semiconductor (solar cell element), such as a silicon cell. The performance of the solar cell element utilized there is deteriorated by contacting the outside air. Consequently, the solar cell element is sandwiched by an encapsulant or a protective film for providing buffering and prevention of contamination with a foreign substance or penetration of moisture.

For a sheet to be used as an encapsulant, a cross-linked ethylene/vinyl acetate copolymer, whose vinyl acetate content is from 25% to 33% by mass, is generally used from viewpoints of transparency, flexibility, processability, and durability (see, for example, Patent Document 1). Meanwhile, in case the vinyl acetate content of an ethylene/vinyl acetate copolymer becomes higher, higher becomes the moisture permeability thereof. In case the moisture permeability becomes higher, depending on the type or the adhesion condition of an upper transparent protective material to be arranged on the side of a solar cell module on which sunlight is incident, a back sheet to be arranged on the side opposite to the side on which sunlight is incident, or the like, the adhesive property with the upper transparent protective material or the back sheet may be deteriorated. Therefore, a back sheet having high barrier is utilized and furthermore a butyl rubber having high barrier is utilized to seal the circumference of a module aiming for preventing moisture.

To ensure such a high moisture proof effect is an inevitable technical element from the viewpoint of durability. Not only the moisture proof effect but also the effect of maintaining a high transparency is essential considered from the nature of undergoing photoelectric conversion by using the incident sunlight. In connection with the above circumstances, for example, as an encapsulant film for a solar cell module, a multilayer laminated film including at least three layers of ionomer films, in which at least two layers among the three layers are chemically different from each other, has been disclosed (see, for example, Patent Document 2), and it is said that the multilayer laminated film is optically transparent.

Further, a solar cell module has been disclosed (see, for example, Patent Document 3), which uses an encapsulant including a laminated body having a first outer layer that contains a first ionomer, a core layer unit which contacts with the first outer layer and contains a polymer layer that uses a non-ionomer polymer, and a second outer layer which contacts with the core layer unit and contains a second ionomer. In this document, it is described that the first ionomer and the second ionomer preferably have the same composition.

Furthermore, a solar cell module having a sealing layer that contains an ionomer composition derived from an acid copolymer has been disclosed. In this document, it is described that the acid copolymer in the sealing layer is a substance that has been neutralized with an ion of a metal selected from the group consisting of sodium, lithium, magnesium, zinc, aluminum, and the like (see, for example, Patent Document 4).

On the other hand, it is known that an ionomer of an ethylene-unsaturated carboxylic acid copolymer is utilized as an interlayer for laminated glass, which is to be interposed between two sheet-like (plate-like) glasses (hereinafter, may also be referred to as “glass sheets”).

Regarding the interlayer for laminated glass, for example, an interlayer for laminated glass, which includes an ethylene-(meth)acrylic acid-(meth)acrylic acid ester copolymer having a specific composition ratio or an ionomer thereof has been disclosed (see, for example, Patent Document 5).

Further, pasted glass in which an ethylene-unsaturated carboxylic acid copolymer, an ethylene-unsaturated carboxylic acid-unsaturated carboxylic acid ester copolymer, or an ionomer thereof is used for a core layer and the two sides of the core layer are laminated with glass has been disclosed (see, for example, Patent Document 6).

Laminated glass obtained by interposing a substance, which is prepared by compounding an organic peroxide and a silane coupling agent to an ionomer of an ethylene-methacrylic acid copolymer, between glass plates, followed by carrying out thermal curing to be integrated has been disclosed (see, for example, Patent Document 7).

Laminated glass obtained by using an ionomer of an ethylene-(meth)acrylic acid copolymer, which has been neutralized by polyamine, for an intermediate adhesive layer, and pasting two glass sheets to the intermediate adhesive layer has been disclosed (see, for example, Patent Document 8).

Moreover, an interlayer for laminated glass, which is formed from a laminated sheet of an ionomer of an ethylene-(meth)acrylic acid copolymer and an ethylene-vinyl acetate copolymer, has been disclosed (see, for example, Patent Document 9).
Patent Document 1: Japanese Patent Application Publication (JP-B) No. 62-14111
Patent Document 2: Japanese Patent Application Laid-Open (JP-A) No. 2008-503366
Patent Document 3: JP-A No. 2008-522877
Patent Document 4: JP-A No. 2009-545185
Patent Document 5: JP-A No. 8-295541
Patent Document 6: JP-A No. 8-295543
Patent Document 7: JP-A No. 9-30846
Patent Document 8: PCT Japanese Translation Patent Publication No. 2002-503627
Patent Document 9: JP-A No. 2009-298046

### DISCLOSURE OF THE INVENTION

### Problem to be Solved by the Invention

As described above, heretofore, ionomers are used as an encapsulant or an interlayer for laminated glass. In all of the above Patent Documents 5 to 9 relating to the interlayer, one kind of ionomer is used in the ionomer layer, which is used as an interlayer in the form of a monolayer.

Various studies have been made of the ionomers from the viewpoints of maintaining high durability as well as high transparency. However, by only using an ionomer as a component of an encapsulant, for example, by using a generally used zinc ionomer or the like, a high transparency may not always be obtained, and especially in the region from around 400 nm to around 600 nm, which is the center of visible region, there is a tendency toward a lowering in light transmission, as compared with the case of using an ionomer (Na ionomer) containing sodium (Na) or an ionomer (Mg ionomer) containing magnesium (Mg).

On the other hand, the Na ionomer and the Mg ionomer have relatively week adhesion to, for example, a glass substrate, a rear face protecting sheet (a so-called back sheet), which is provided on the side opposite to the side on which sunlight is incident in the preparation of a solar cell module, or the like, and thus, there is concern about degradation over time (peeling or the like).

The present invention has been made in view of the above circumstances. Under such circumstances, a multilayer material (for example, an encapsulant for a solar cell or an interlayer for safety (laminated) glass) which has excellent transparency and excellent adhesiveness to an adherend (for example, a glass substrate, a resin sheet (a back sheet) for protecting the rear face of a solar cell module, or the like) is required. Further, a solar cell module or safety (laminated) glass which has more excellent long term durability as compared with conventional products is required.

### Means for Solving the Problems

The present invention is based on the finding that, among ionomers, a sodium (Na) ionomer and a magnesium (Mg) ionomer have good transparency, but have week adhesion to, for example, glass, a resin sheet (a so-called back sheet) for protecting the rear face of a solar cell module, or the like, and thus, have a tendency toward lowering in adhesiveness by being degraded with time.

From this point of view, specific means for achieving the objects described above are as follows. Namely,

the first invention for achieving the above objects includes the followings.

<1> A multilayer material having a layer (A) including a silane coupling agent and an ethylene type zinc ionomer; and a layer (B) comprising at least one of an ethylene type magnesium ionomer or an ethylene type sodium ionomer.

The multilayer material of the present invention is suitable for use as an encapsulant for a solar cell (encapsulant for photovoltalic (solar) cells; hereinafter the same applies) to seal a solar cell element (photovoltalic cells) provided on a substrate, or an interlayer for safety glass (laminated glass) (hereinafter the same applies) which is to be arranged between two glass sheets.

<2> The multilayer material (for example, an encapsulant for a solar cell or an interlayer for safety (laminated) glass) as described in the above <1>, having at least two of the layer (A) and at least one of the layer (B), and including a multilayered structure in which one of the layer (B) is interposed between two of the layer (A).

<3> The multilayer material (for example, an encapsulant for a solar cell or an interlayer for safety (laminated) glass) as described in the above <1> or <2>, wherein, in the layer (B), a content ratio of a silane coupling agent is 0.1% by mass or lower relative to a solid content of the layer (B).

<4> The multilayer material (for example, an encapsulant for a solar cell or an interlayer for safety (laminated) glass) as described in any one of the above <1> to <3>, wherein the layer (A) contains dialkoxysilane having an amino group (a silane coupling agent having an amino group and two alkoxy groups) in an amount of 3 parts by mass or less relative to 100 parts by mass of the ethylene type zinc ionomer.

<5> The multilayer material (for example, an encapsulant for a solar cell or an interlayer for safety (laminated) glass) as described in any one of the above <1> to <4>, wherein the total thickness of the thickness of the layer (A) and the thickness of the layer (B) is from 0.1 mm to 2 mm.

<6> The multilayer material (for example, an encapsulant for a solar cell or an interlayer for safety (laminated) glass) as described in any one of the above <1> to <5>, wherein a ratio (a/b) of a thickness a of the layer (A) to a thickness b of the layer (B) is from 1/1 to 1/20.

<7> The multilayer material (for example, an encapsulant for a solar cell or an interlayer for safety (laminated) glass) as described in any one of the above <1> to <6>, wherein the melt flow rates (MFR; JIS K 7210-1999, at 190° C., under a load of 2160 g) of the ethylene type zinc ionomer in the layer (A) and the at least one of the ethylene type magnesium ionomer or the ethylene type sodium ionomer in the layer (B) are respectively from 0.1 g/10 min to 150 g/10 min.

<8> The multilayer material (for example, an encapsulant for a solar cell or an interlayer for safety (laminated) glass) as described in any one of the above <1> to <7>, wherein the melt flow rate of the ethylene type zinc ionomer in the layer (A) (MFR; JIS K 7210-1999, at 190° C., under a load of 2160 g) is higher than the melt flow rate of the at least one of the ethylene type magnesium ionomer or the ethylene type sodium ionomer in the layer (B).

<9> The multilayer material (for example, an encapsulant for a solar cell or an interlayer for safety (laminated) glass) as described in any one of the above <1> to <8> having a light transmission in accordance with JIS-K 7105 of 88% or higher, when subjected to pasting in a state of being interposed between two sheets of float glass each having a thickness of 3.2 mm, using a double vacuum chamber pasting apparatus under conditions of 150° C. for 8 minutes, followed by cooling in ambient air at 23° C.

<10> The multilayer material (for example, an encapsulant for a solar cell or an interlayer for safety (laminated) glass) as described in any one of the above <1> to <9>, wherein at least one of the layer (A) or the layer (B) further contains one or more additives selected from the group consisting of ultraviolet absorbents, light stabilizers, and antioxidants.

<11> The multilayer material (for example, an encapsulant for a solar cell or an interlayer for safety (laminated) glass) as described in any one of the above <1> to <10>, wherein the ethylene type zinc ionomer has an ionomer of an ethylene-acrylic acid copolymer or an ethylene-methacrylic acid copolymer, and the at least one of the ethylene type magnesium ionomer or the ethylene type sodium ionomer has an ionomer of an ethylene-acrylic acid copolymer or an ethylene-methacrylic acid copolymer.

<12> The multilayer material (for example, an encapsulant for a solar cell or an interlayer for safety (laminated) glass) as described in any one of the above <1> to <11>, wherein a content ratio of the ethylene type zinc ionomer in the layer (A) is 60% by mass or more relative to a total mass of the layer (A), and a content ratio of a total amount of the ethylene type magnesium ionomer and the ethylene type sodium ionomer in the layer (B) is 60% by mass or more relative to a total mass of the layer (B).

<13> The multilayer material (for example, an encapsulant for a solar cell or an interlayer for safety (laminated) glass) as described in any one of the above <1> to <12>, wherein a content ratio of the ethylene type magnesium ionomer in the layer (B) is 80% by mass or higher relative to a total amount of a resin material including the ionomers.

Further, the second invention is as follows.

<14> A solar cell module having the multilayer material as described in any one of the above <1> to <13>, as an encapsulant for a solar cell.

Moreover, the third invention is as follows.

<15> Safety glass (laminated glass) having the multilayer material as described in any one of the above <1> to <13>, as an interlayer for safety glass (laminated glass).

### Effects of the Invention

According to the present invention, a multilayer material (for example, an encapsulant for a solar cell or an interlayer for safety (laminated) glass) which has excellent transparency and excellent adhesiveness to an adherend (for example, a glass substrate, a resin sheet (a back sheet) for protecting the rear face of a solar cell module, or the like) may be provided. Further, according to the present invention, a solar cell module or safety (laminated) glass which has more excellent long term durability as compared with conventional products may be provided.

### BEST MODES FOR CARRYING OUT THE INVENTION

Hereinafter, a multilayer material (including an encapsulant for a solar cell and an interlayer for safety (laminated) glass) of the present invention, and a solar cell module and safety (laminated) glass which are provided with the multilayer material are described in detail.

The multilayer material of the present invention is configured to include a layer (A) that contains a silane coupling agent and an ethylene type zinc ionomer, and a layer (B) that contains at least one of an ethylene type magnesium ionomer or an ethylene type sodium ionomer. The layer (A) and the layer (B) may contain other components such as an ultraviolent absorbent, a light stabilizer, or an antioxidant, as necessary. Further, the layer (A) and the layer (B) may contain a pigment (an organic pigment or an inorganic pigment), a dye, or the like, as a colorant.

The multilayer material of the present invention is suitable for use as encapsulant for a photovoltaic (solar) cell to seal solar cell elements (photovoltaic cells) provided on a substrate, or as an interlayer for safety (laminated) glass which is to be arranged between two glass sheets.

In the present invention, by the use of ionomers, the heat resistance, flexibility, moldability, and the like can be maintained. In this case, by constituting a multilayered structure provided with a layer that contains at least an ethylene type magnesium ionomer and/or an ethylene type sodium ionomer, and a layer that contains at least an ethylene type zinc ionomer, a high transparency and also excellent adhesiveness to the adherend such as a glass substrate or a base material such as a back sheet of a solar cell module or the like (for example, when used as an encapsulant for a solar cell module, an adjacent material that is in contact with the encapsulant) may be obtained.

Further, a crosslinking process using an organic peroxide or the like, as described in Patent Document 7, is made unnecessary, so that molding can be performed by an easier method in a short time as compared with conventional methods, and a product suitable for the application for sealing of solar cell elements or application to an interlayer for safety (laminated) glass may be provided.

From the viewpoints of the adhesiveness and the transparency, it is preferable the layer (A) in the present invention contains an ethylene type zinc ionomer as a main component. Further, it is particularly preferable that the layer (B) contains an ethylene type magnesium ionomer and/or an ethylene type sodium ionomer as a main component. The expression “containing an ionomer as a main component” means that, in the layer (A), the proportion of the “ethylene type zinc ionomer” is 60% by mass or higher relative to the total mass of the layer. In the layer (B), the above expression means that the proportion of the total amounts of the “ethylene type magnesium ionomer and/or ethylene type sodium ionomer” is 60% by mass or higher relative to the total mass of the layer.

In the respective layers, the case in which the proportion of the ethylene type zinc ionomer in the layer (A) is 80% by mass or higher, and/or the case in which the proportion of the total amounts of the ethylene type magnesium ionomer and/or the ethylene type sodium ionomer in the layer (B) is 80% by mass or higher are (is) more preferable.

[Layer (A)]

The multilayer material of the present invention has at least one layer (A). The layer (A) contains, among ionomers, an ethylene type zinc(Zn) ionomer (hereinafter, may be abbreviated to “Zn ionomer”). When the Zn ionomer is incorporated, the multilayer material exhibits excellent adhesiveness to a glass substrate or a resin sheet for protecting a rear face (a back sheet which is provided on the side opposite to the side on which sunlight is incident) when the multilayer material is used in a solar cell module, or the like, which is a material to be adhered. Accordingly, peeling at the adhesion interface, which may be caused in the case of constituting an encapsulant by using the below-described layer (B) that contains a Na ionomer, a Mg ionomer (preferably, as a main component), may be prevented, and both the transparency and the durability when used over a long-term may be exhibited.

The ethylene type Zn ionomer incorporated (preferably, as a main component) in the layer (A) is a zinc ionomer of an ethylene-unsaturated carboxylic acid copolymer that has a constituent unit derived from ethylene and a constituent unit derived from an unsaturated carboxylic acid. The content ratio of the constituent unit derived from ethylene in the ethylene-unsaturated carboxylic acid copolymer, which is the base polymer, is preferably from 97% by mass to 75% by mass, and more preferably from 95% by mass to 75% by mass. The content ratio of the constituent unit derived from an unsaturated carboxylic acid is preferably from 3% by mass to 25% by mass, and more preferably from 5% by mass to 25% by mass.

When the content ratio of the constituent unit derived from ethylene is 75% by mass or higher, the heat resistance, the mechanical strength, and the like of the copolymer are excellent. When the content ratio of the constituent unit derived from ethylene is 97% by mass or lower, the adhesiveness and the like are excellent.

In the Zn ionomer, examples of the unsaturated carboxylic acid include acrylic acid, methacrylic acid, maleic acid, maleic anhydride, and maleic anhydride monoester, and particularly, acrylic acid or methacrylic acid is preferable.

A zinc ionomer of an ethylene-acrylic acid copolymer and a zinc ionomer of an ethylene-methacrylic acid copolymer are particularly preferable examples of the ethylene type Zn ionomer.

The constituent unit derived from an unsaturated carboxylic acid in the ethylene-unsaturated carboxylic acid copolymer, which is the base polymer of the Zn ionomer, plays an important role in the adhesiveness to a base material such as glass. The constituent unit derived from an unsaturated carboxylic acid gives adhesiveness to the ethylene type Zn ionomer in the layer (A), which is mainly provided so as to be in contact with a base material such as glass.

The one which has a content ratio of the constituent unit derived from an unsaturated carboxylic acid of 3% by mass or higher relative to the total mass of the ionomer has excellent transparency and excellent flexibility. Further, the one which has a content ratio of the constituent unit derived from an unsaturated carboxylic acid of 25% by mass or lower has suppressed stickiness and excellent processability.

The ethylene-unsaturated carboxylic acid copolymer may contain a constituent unit derived from other copolymerizable monomer in an amount of more than 0% by mass but 30% by mass or less, and preferably more than 0% by mass but 25% by mass or less, relative to 100% by mass of the total amounts of the ethylene and the unsaturated carboxylic acid.

Examples of the other copolymerizable monomer include unsaturated esters, for example, a vinyl ester such as vinyl acetate or vinyl propionate; a (meth)acrylic acid ester such as methyl acrylate, ethyl acrylate, isobutyl acrylate, n-butyl acrylate, 2-ethylhexyl acrylate, methyl methacrylate, or isobutyl methacrylate; and the like. When the constituent unit derived from other copolymerizable monomer is contained in an amount within the above range, the flexibility of the ethylene-unsaturated carboxylic acid copolymer may be enhanced, which is preferable.

The degree of neutralization of the Zn ionomer, which may be used, is usually 80% or less, and is preferably from 5% to 80%. From the viewpoints of processability and flexibility, a Zn ionomer having a degree of neutralization of from 5% to 60% is preferable, and particularly, it is more preferable to use a Zn ionomer having a degree of neutralization of from 5% to 30%.

The ethylene-unsaturated carboxylic acid copolymer, which is the base polymer of the ethylene type Zn ionomer, can be obtained by radical copolymerization using the polymerization components, under high temperature and high pressure. Further, the ionomer thereof can be obtained by reacting the thus obtained ethylene-unsaturated carboxylic acid copolymer with zinc oxide, zinc acetate, or the like.

The ethylene type Zn ionomer preferably has a melt flow rate (MFR; in accordance with JIS K 7210-1999) at 190° C. under a load of 2160 g of from 0.1 g/10 min to 150 g/10 min, and particularly preferably from 0.1 g/10 min to 50 g/10 min, in view of processability and mechanical strength.

In the present invention, from the viewpoint of easiness of processing to obtain a multilayer sheet as an encapsulant for a solar cell module, an interlayer for safety (laminated) glass, or the like, it is preferable that the MFR of the ethylene type Zn ionomer in the layer (A) is higher than the MFR of the ethylene type Mg ionomer and/or the ethylene type Na ionomer in the layer (B) described below. Above all, particularly, it is preferable that the MFR of the ethylene type Zn ionomer is higher than the MFR of the ethylene type Mg ionomer and/or the ethylene type Na ionomer by 0.5 g/10 min or more, and further preferably by 2 g/10 min or more.

There is no particular limitation as to the melting point of the ethylene type Zn ionomer, but when the ethylene type Zn ionomer has a melting point of 90° C. or higher, particularly 95° C. or higher, heat resistance may be improved, which is preferable.

The layer (A) that constitutes the multilayer material of the present invention preferably contains the ethylene type Zn ionomer in an amount of 60% by mass or more, more preferably 70% by mass or more, and even more preferably in a range of 80% by mass or more, with respect to the content of solids in the layer. When the ethylene type Zn ionomer is contained in an amount within the above range, a excellent adhesion, a excellent durability, and the like may be obtained while maintaining high transparency.

As described above, in a case in which the layer (A) is not a 100% by mass of ethylene type Zn ionomer, other resin material may be compounded together with the ionomer. The resin material which is compounded in this case may be any material as far as the resin material has good mutual solubility with the Zn ionomer and does not damage the transparency or mechanical properties. Above all, an ethylene-unsaturated carboxylic acid copolymer and an ethylene-unsaturated ester-unsaturated carboxylic acid copolymer are preferable. When the resin material that is compounded together with the Zn ionomer is a resin material having a melting point higher than the melting point of the Zn ionomer, it is also possible to enhance the heat resistance or durability of the layer (A).

Among the layer (A) and the below-described layer (B) of the multilayer material of the present invention, at least the layer (A) contains at least one silane coupling agent. Together with the layer (A), the layer (B) may also contain a silane coupling agent.

Examples of the silane coupling agent may include γ-methacryloxypropyltrimethoxysilane, γ-methacryloxypropylmethyldimethoxysilane, γ-acryloxypropyltrimethoxysilane, γ-acryloxypropylmethyldimethoxysilane, N-(β-aminoethyl)-γ-aminopropyltrimethoxysilane, N-(β-aminoethyl)-γ-aminopropylmethyldimethoxysilane, γ-aminopropyltriethoxysilane, and γ-glycidoxypropyltrimethoxysilane.

Above all, as the silane coupling agent, a silane coupling agent having an amino group and an alkoxy group is preferable, in view of enhancing the adhesiveness and stably performing the adhesion processing to a base material such as glass, a back sheet, or the like.

Specific examples of the silane coupling agent having an amino group and an alkoxy group, which may be compounded to an ethylene type Zn ionomer, may include amino-trialkoxysilanes such as 3-aminopropyltrimethoxysilane, 3-aminopropyltriethoxysilane, or N-(2-aminoethyl)-3-aminopropyltrimethoxysilane; and amino-dialkoxysilanes such as N-(2-aminoethyl)-3-aminopropylmethyldimethoxysilane, N-(2-aminoethyl)-3-aminopropylmethyldiethoxysilane, N-(2-aminoethyl)-3-aminopropyldimethoxysilane, 3-aminopropylmethyldimethoxysilane, 3-aminopropylmethyldiethoxysilane, N-phenyl-3-aminopropylmethyldimethoxysilane, N-phenyl-3-aminopropylmethyldiethoxysilane, 3-methyldimethoxysilyl-N-(1,3-dimethyl-butylidene)propylamine, or 3-methyldimethoxysilyl-N-(1,3-dimethyl-butylidene)propylamine.

Among them, N-(2-aminoethyl)-3-aminopropylmethyldimethoxysilane, N-(2-aminoethyl)-3-aminopropylmethyldiethoxysilane, N-(2-aminoethyl)-3-aminopropylethyldimethoxysilane, 3-aminopropylmethyldimethoxysilane, 3-aminopropylmethyldiethoxysilane, and the like are preferable. Particularly, a silane coupling agent having an amino group and two alkoxy groups such as N-(2-aminoethyl)-3-aminopropylmethyldimethoxysilane is preferable.

When a silane coupling agent having an amino group and two alkoxy groups (which may be abbreviated to “dialkoxy silane”) is used, the processing stability during sheet molding can be further maintained, which is more preferable.

In the layer (A), from the viewpoints of the effect of improvement in adhesiveness and the processing stability during sheet molding, the silane coupling agent (especially, the silane coupling agent having an amino group and an alkoxy group) is preferably compounded at a proportion of higher than 0 parts by mass but 3 parts by mass or lower, more preferably from 0.03 parts by mass to 3 parts by mass, and particularly preferably from 0.05 parts by mass to 1.5 parts by mass, relative to 100 parts by mass of the ethylene type Zn ionomer. When the silane coupling agent is contained at a proportion within the above range, the adhesiveness between the encapsulant for a solar cell and a protection material, a solar cell element, or the like may be improved.

The layer (A) can contain various additives to the extent not impairing the purpose of the invention. Examples of such additives include an ultraviolet absorbent, a light stabilizer, and an antioxidant.

In order to prevent the degradation of the multilayer sheet due to exposure with ultraviolet rays, it is preferable that an ultraviolet absorbent, a light stabilizer, an antioxidant, and the like are incorporated in the layer (A).

Examples of the ultraviolet absorbent include benzophenone type ultraviolet absorbents such as 2-hydroxy-4-methoxybenzophenone, 2,2′-dihydroxy-4-methoxybenzophenone, 2-hydroxy-4-methoxy-2-carboxybenzophenone, or 2-hydroxy-4-n-octoxybenzophenone; benzotriazole type ultraviolet absorbents such as 2-(2′-hydroxy-3′,5′-di-t-butylphenyl)benzotriazole, 2-(2′-hydroxy-5-methylphenyl)benzotriazole, or 2-(2′-hydroxy-5-t-octylphenyl)benzotriazole; and salicylate ester type ultraviolet absorbents such as phenyl salicylate or p-octylphenyl salicylate.

As the light stabilizer, a hindered amine type light stabilizer is used. Examples of the hindered amine type light stabilizer may include 4-acetoxy-2,2,6,6-tetramethylpiperidine, 4-stearoyloxy-2,2,6,6-tetramethylpiperidine, 4-acryloyloxy-2,2,6,6-tetramethylpiperidine, 4-benzoyloxy-2,2,6,6-tetramethylpiperidine, 4-cyclohexanoyloxy-2,2,6,6-tetramethylpiperidine, 4-(o-chlorobenzoyloxy)-2,2,6,6-tetramethylpiperidine, 4-(phenoxyacetoxy)-2,2,6,6-tetramethylpiperidine, 1,3,8-triaza-7,7,9,9-tetramethyl-2,4-dioxo-3-n-octyl-spiro[4,5]decane, bis(2,2,6,6-tetramethyl-4-piperidyl) sebacate, bis(2,2,6,6-tetramethyl-4-piperidyl) terephthalate, bis(1,2,2,6,6-pentamethyl-4-piperidyl) sebacate, tris(2,2,6,6-tetramethyl-4-piperidyl)benzene-1,3,5-tricarboxylate, tris(2,2,6,6-tetramethyl-4-piperidyl)-2-acetoxypropane-1,2,3-tricarboxylate, tris(2,2,6,6-tetramethyl-4-piperidyl)-2-hydroxypropane-1,2,3-tricarboxylate, tris(2,2,6,6-tetramethyl-4-piperidyl)triazine-2,4,6-tricarboxylate, tris(2,2,6,6-tetramethyl-4-piperidine) phosphite, tris(2,2,6,6-tetramethyl-4-piperidyl)butane-1,2,3-tricarboxylate, tetrakis(2,2,6,6-tetramethyl-4-piperidyl)propane-1,1,2,3-tetracarboxylate, and tetrakis(2,2,6,6-tetramethyl-4-piperidyl)butane-1,2,3,4-tetracarboxylate.

As the antioxidant, a hindered phenol type antioxidant or a phosphite type antioxidant is used. Specific examples of the hindered phenol type antioxidant may include 2,6-di-t-butyl-p-cresol, 2-t-butyl-4-methoxyphenol, 3-t-butyl-4-methoxyphenol, 2,6-di-t-butyl-4-ethylphenol, 2,2′-methylenebis(4-methyl-6-t-butylphenol), 2,2′-methylenebis(4-ethyl-6-t-butylphenol), 4,4′-methylenebis(2,6-di-t-butylphenol), 2,2′-methylenebis[6-(1-methylcyclohexyl)-p-cresol], bis[3,3-bis(4-hydroxy-3-t-butylphenyl)butyric acid] glycol ester, 4,4′-butylidenebis(6-t-butyl-m-cresol), 2,2′-ethylidenebis(4-sec-butyl-6-t-butylphenol), 2,2′-ethylidenebis(4,6-di-t-butylphenol), 1,1,3-tris(2-methyl-4-hydroxy-5-t-butylphenyl)butane, 1,3,5-tris(3,5-di-t-butyl-4-hydroxybenzyl)-2,4,6-trimethylbenzene, 2,6-diphenyl-4-octadecyloxyphenol, tetrakis[methylene-3-(3,5-di-t-butyl-4-hydroxyphenyl)propionato]methane, n-octadecyl-3-(3,5-di-t-butyl-4-hydroxyphenyl) propionate, 4,4′-thiobis(6-t-butyl-m-cresol), tocopherol, 3,9-bis[1,1-dimethyl-2-[β-(3-(3-t-butyl-4-hydroxy-5-methylphenyl)propionyloxy]ethyl]2,4,8,10-tetraoxaspiro[5,5]undecane, and 2,4,6-tris(3,5-di-t-butyl-4-hydroxybenzylthio)-1,3,5-triazine.

Further, specific examples of the phosphite type antioxidant may include 3,5-di-t-butyl-4-hydroxybenzylphosphanate dimethyl ester, ethyl bis(3,5-di-t-butyl-4-hydroxybenzylphosphonate, and tris(2,4-di-t-butylphenyl)phosphanate.

The antioxidant, the light stabilizer, and the ultraviolet absorbent each can be contained in an amount of, generally, 5 parts by mass or less, and preferably from 0.1 parts by mass to 3 parts by mass, relative to 100 parts by mass of the ethylene type Zn ionomer.

Furthermore, other than the additives described above, additives such as a colorant, a light diffusing agent, a flame retardant, or a metal deactivator can be incorporated in the layer (A), as necessary.

Examples of the colorant include a pigment, an inorganic compound, and a dye. As the colorant, various known colorants can be used. Specifically, examples of a white colorant include titanium oxide, zinc oxide, and calcium carbonate. When a multilayer sheet containing these colorants is used as an encapsulant on the light-receiving side of a solar cell element, the transparency may be spoiled; however, in the case of using a multilayer sheet as an encapsulant on the opposite side of a solar cell element from the light-receiving side, a multilayer sheet containing these colorants is preferably used.

Among the above pigments, examples of inorganic pigments include white inorganic pigments such as titanium oxide, zinc oxide, lead white, lithopone, barite, precipitated barium sulfate, calcium carbonate, gypsum, or precipitated silica; black inorganic pigments such as carbon black, lamp black, black titanium oxide, or synthetic iron black; gray inorganic pigments such as zinc dust, lead suboxide, or slate powder; red inorganic pigments such as cadmium red, Cadmium Mercury Red, vermilion, red iron oxide, molybdenum red, or red lead; brown inorganic pigments such as umber or iron oxide brown; yellow inorganic pigments such as cadmium yellow, zinc yellow, ochre, sienna, synthetic ochre, chrome yellow, titanium yellow; green inorganic pigments such as chromic oxide green, cobalt green, or chrome green; blue inorganic pigments such as ultramarine, Prussian blue, iron blue, or cobalt blue; and metal powder inorganic pigments.

Further, examples of organic pigments include azo pigments such as Permanent Red 4R, Para Red, Fast Yellow G, Fast Yellow 10G, Disazo Yellow G, Disazo Yellow GR, disazo orange, Pyrazolone Orange, Brilliant Carmine 3B, Brilliant Carmine 6B, Brilliant Scarlet G, Brilliant Bordeaux 10B, Bordeaux 5B, Permanent Red FSR, Permanent Carmine FB, Lithol Red R, Lithol Red B, Lake Red C, Lake Red D, Brilliant Fast Scarlet, Pyrazolone Red, BON Maroon Light, BON Maroon Medium, or Fire Red; nitroso pigments such as Naphthol Green B; nitro pigments such as Naphthol Yellow S; basic dye-based lake such as Rhodamine B Lake or Rhodamine 6G Lake; mordant dye-based lake such as Alizarin Lake; vat dye-based pigments such as Indanthrene Blue; phthalocyanine pigments such as Phthalocyanine Blue, Phthalocyanine Green, or Fast Sky Blue; and dioxazine-based pigments such as Dioxazine Violet.

Other than the above pigments, organic fluorescent pigments, pearl pigments, and the like are usable.

Examples of the light diffusing agent include, as inorganic spherical substances, glass beads, silica beads, silicone alkoxide beads, and hollow glass beads. As organic spherical substances, plastic beads such as acrylic or vinylbenzene-based plastic beads, and the like are described.

Examples of the flame retardant include halogen-containing flame retardants such as bromides, phosphorous-containing flame retardants, silicone-containing flame retardants, and metal hydrates such as magnesium hydroxide, aluminum hydroxide, or the like.

As the metal deactivator, those known as compounds that suppress metal damage of thermoplastic resins can be used. Two or more types of the metal deactivators may be used in combination. Preferable examples of the metal deactivator may include hydrazide derivatives and triazole derivatives. Specifically, preferable examples of the metal deactivator include hydrazide derivatives such as decamethylenedicarboxyl-di-salicyloylhydrazide, 2′,3-bis[3-[3,5-di-tert-butyl-4-hydroxyphenyl]propionyl]propionohydrazide, or bis(2-phenoxypropionyl-hydrazide) isophthalate; and triazole derivatives such as 3-(N-salicyloyl)amino-1,2,4-triazole. Other than the hydrazide derivatives and the triazole derivatives, examples may also include 2,2′-dihydroxy-3,3′-di-(α-methylcyclohexyl)-5,5′-dimethyl•diphenylmethane, tris-(2-methyl-4-hydroxy-5-tert-butylphenyl)butane, and a mixture of 2-mercaptobenzimidazole and a phenol condensate.

[Layer (B)]

The multilayer material of the present invention has at least one layer (B). The layer (B) contains, among iomoners, at least one of an ethylene type sodium (Na) ionomer or an ethylene type magnesium (Mg) ionomer (hereinafter, these ionomers may be abbreviated to “Na ionomer” and “Mg ionomer”, respectively).

By containing an Na ionomer and/or an Mg ionomer as the resin material that constitutes an encapsulant for a solar cell or an interlayer for safety (laminated) glass, the transparency of the whole encapsulant or the whole interlayer for safety (laminated) glass can be improved significantly.

The ethylene type Na ionomer contained in the layer (B) (preferably, as a main component) is an Na ionomer of an ethylene-unsaturated carboxylic acid copolymer having a constituent unit derived from ethylene and a constituent unit derived from an unsaturated carboxylic acid. Further, the ethylene type Mg ionomer contained in the layer (B) (preferably, as a main component) is an Mg ionomer of an ethylene-unsaturated carboxylic acid copolymer having a constituent unit derived from ethylene and a constituent unit derived from an unsaturated carboxylic acid.

The content ratio of the constituent unit derived from ethylene in the ethylene-unsaturated carboxylic acid copolymer, which is the base polymer, is preferably from 97% by mass to 75% by mass, and more preferably from 95% by mass to 75% by mass. The content ratio of the constituent unit derived from an unsaturated carboxylic acid is preferably from 3% by mass to 25% by mass, and more preferably from 5% by mass to 25% by mass.

When the content ratio of the constituent unit derived from ethylene is 75% by mass or higher, the heat resistance, the mechanical strength, and the like of the copolymer are excellent. When the content ratio of the constituent unit derived from ethylene is 97% by mass or lower, the adhesiveness and the like are excellent.

In the Na ionomer and Mg ionomer, examples of the unsaturated carboxylic acid include acrylic acid, methacrylic acid, maleic acid, maleic anhydride, and maleic anhydride monoester, and particularly, acrylic acid or methacrylic acid is preferable.

Above all, an Na ionomer and Mg ionomer of an ethylene-acrylic acid copolymer and an Na ionomer and Mg ionomer of an ethylene-methacrylic acid copolymer are particularly preferable examples of the ethylene type Na ionomer or the ethylene type Mg ionomer.

In the Na ionomer and Mg ionomer, the constituent unit derived from an unsaturated carboxylic acid in the ethylene-unsaturated carboxylic acid copolymer, which is the base polymer, plays an important role in the adhesiveness to a base material such as glass. The Na ionomer and Mg ionomer in the layer (B), which may not always be adhered to a base material such as glass, have relatively low adhesiveness, but the constituent unit derived from an unsaturated carboxylic acid also contributes to the improvement in the adhesiveness.

The one which has a content ratio of the constituent unit derived from an unsaturated carboxylic acid of 3% by mass or higher, relative to the total mass of the ionomer, has excellent transparency and excellent flexibility. Further, the one which has a content ratio of the constituent unit derived from an unsaturated carboxylic acid of 25% by mass or lower has suppressed stickiness and excellent processability.

Similarly to the case of the Zn ionomer described above, the ethylene-unsaturated carboxylic acid copolymer of the Na ionomer or Mg ionomer may contain a constituent unit derived from other copolymerizable monomer in an amount of more than 0% by mass but 30% by mass or less, and preferably more than 0% by mass but 25% by mass or less, relative to 100% by mass of the total amounts of the ethylene and the unsaturated carboxylic acid.

Examples of the other copolymerizable monomer include unsaturated esters, for example, a vinyl ester such as vinyl acetate or vinyl propionate; a methacrylic acid ester such as methyl acrylate, ethyl acrylate, isobutyl acrylate, n-butyl acrylate, 2-ethylhexyl acrylate, methyl methacrylate, or isobutyl methacrylate; and the like. When the constituent unit derived from other copolymerizable monomer is contained in an amount within the above range, flexibility of the ethylene-unsaturated carboxylic acid copolymer may be enhanced, which is preferable.

The degree of neutralization of the Na ionomer and Mg ionomer, which may be used, is usually 80% or less, and is preferably from 5% to 80%. From the viewpoints of processability and flexibility, it is preferable to use an Na ionomer and an Mg ionomer which have a degree of neutralization of from 5% to 60%, and particularly preferably from 5% to 30%.

The ethylene-unsaturated carboxylic acid copolymer, which is the base polymer of the Na ionomer and the Mg ionomer, can be obtained by radical copolymerization using the polymerization components, under high temperature and high pressure. Further, the ionomer thereof can be obtained by reacting the thus obtained ethylene-unsaturated carboxylic acid copolymer with zinc oxide, zinc acetate, or the like.

The Na ionomer and the Mg ionomer preferably have a melt flow rate (MFR; in accordance with JIS K 7210-1999) at 190° C. under a load of 2160 g of from 0.1 g/10 min to 150 g/10 min, and particularly preferably from 0.1 g/10 min to 50 g/10 min, in view of processability and mechanical strength.

There is no particular limitation as to the melting point of the Na ionomer and the Mg ionomer, but the melting point is preferably 85° C. or higher, and particularly preferably 90° C. or higher, in view of improving the heat resistance.

The layer (B) that constitutes the multilayer material of the present invention preferably contains the ethylene type Na ionomer and/or the ethylene type Mg ionomer in a total amount of 60% by mass or more, and more preferably 70% by mass or more, with respect to the content of solids in the layer. When the content of the ethylene type Na ionomer and/or the ethylene type Mg ionomer is within the above range, the transparency (for example, the transparency of an encapsulant or an interlayer for safety (laminated) glass) may be improved significantly. When a solar cell is produced, the power generation efficiency can be more effectively enhanced than heretofore.

Among the above, from the viewpoint of more effectively improving the transparency (for example, the transparency of an encapsulant or an interlayer for safety (laminated) glass), it is preferable that the layer (B) contains the ethylene type Mg ionomer, and further, it is particularly preferable that the layer (B) contains the ethylene type Mg ionomer in an amount of 80% by mass or more, relative to a total amount of the resin material including the ionomers.

In a case in which the layer (B) does not have a composition that includes 100% by mass of the ethylene type Na ionomer and/or the ethylene type Mg ionomer as the resin component, other resin material can be compounded together with the ionomer. The resin material which is compounded in this case may be any material as far as the resin material has good mutual solubility with the Na ionomer and/or the Mg ionomer, and does not damage the transparency or mechanical properties. Above all, an ethylene-unsaturated carboxylic acid copolymer and an ethylene-unsaturated ester-unsaturated carboxylic acid copolymer are preferable. When the resin material that is compounded together with the Na ionomer and/or the Mg ionomer is a resin material having a melting point higher than the melting point(s) of the Na ionomer and/or the Mg ionomer, it is also possible to enhance the heat resistance or durability of the layer (B).

The layer (B) may include various additives to the extent of not impairing the purposes of the invention. Examples of such additives may include all of the additives described above as the additives that may be included in the above layer (A). In a case in which the additive is contained in the layer (B), the additive may be contained in an amount the same as the amount of the additive contained in the layer (A).

In the present invention, the layer (A) contains a silane coupling agent, but the layer (B), together with the layer (A), may also contain a silane coupling agent. In the present invention, for example, when the layer constitution including the layer (A) and the layer (B) is made to be “layer (A)/layer (B)/layer (A)” or the like, the layer (B) is not required to have adhesiveness with a material other than the layer (A) and therefore, it is preferable that the layer (B) does not substantially contain a silane coupling agent. And, specifically, from the viewpoint of production stability, it is preferable that the content ratio of a silane coupling agent in the layer (B) is 0.1% by mass or lower of the solids content of the layer (B). Further, it is particularly preferable that a silane coupling agent is not contained (0% by mass) in the layer (B).

The multilayer material of the present invention has an layer (A) that contains an ethylene type Zn ionomer and a silane coupling agent, and a layer (B) that contains an ethylene type Mg ionomer and/or an ethylene type Na ionomer. The total thickness of the multilayer material including the layer (A) and the layer (B) is preferably within the following range. Namely,

for example, when the multilayer material is used as an encapsulant for a solar cell, the total thickness of the encapsulant for a solar cell is preferably in a range of from 0.1 mm to 2 mm. The preferable range of this total thickness is from 0.2 mm to 1.5 mm. When the total thickness of the encapsulant for a solar cell is 0.1 mm or more, the material is suitable for sealing solar cell elements, wires, and the like, and when the total thickness is 2 mm or less, the transparency of the encapsulant for a solar cell becomes excellent, and the encapsulant for a solar cell exhibits excellent designability.

Further, when the multilayer material is used as an interlayer for safety (laminated) glass, the total thickness of the interlayer for safety (laminated) glass is preferably from 5 μm to 2000 μm (from 0.005 mm to 2 mm), more preferably in a range of from 100 μm to 2000 μm (from 0.1 mm to 2 mm), and even more preferably in a range of from 100 μm to 1000 μm (from 0.1 mm to 1 mm). When the total thickness of the interlayer for safety (laminated) glass is within this range, an interlayer for safety (laminated) glass which has excellent adhesiveness and excellent transparency while achieving economic efficiency, namely, with an appropriate cost as a product, may be provided.

The layer (A) which constitutes the multilayer material preferably has a structure in which one layer containing an ethylene type Zn ionomer is formed, but may be a form in which plural layers having different compositions of the ethylene type Zn ionomer, or different ratios of the other copolymerizable monomer contained in the ethylene-unsaturated carboxylic acid copolymer (preferably, ethylene-(meth)acrylic acid copolymer), or the like are formed.

The layer (A) is provided by laminating on one side or two sides of the layer (B). In the present invention, from the viewpoint of the adhesiveness to a glass substrate, a back sheet for protecting a rear face when forming a solar cell module, or the like, it is preferable to provide at least two of the layer (A) and at least one of the layer (B) and to form a laminate structure of “layer (A)/layer (B)/layer (A)” in which the layer (B) is interposed between the two of the layer (A). Further, the multilayer material of the present invention may include three or more of the layer (A) and two or more of the layer (B). In this case, any structure may be formed as far as the structure is a layer structure expressed by [layer (A)/ . . . layer (B) . . . /layer (A)], in which the layer that forms the outermost layer, one side of which is exposed, is the layer (A).

The layer (B) which is disposed on one side of the layer (A) preferably has, similar to the layer (A), a structure in which a single layer is formed, but may have a laminate structure in which plural layers each containing a different ethylene type Na or Mg ionomer as a main component are formed.

As described above, the multilayer material of the present invention is a material in which plural layers including the layer (A) and the layer (B) are laminated, and is preferably a three-layer sheet which contains an intermediate layer formed from the layer (B) and two outer layers, which are provided on the two sides of the intermediate layer so as to sandwich the intermediate layer and are formed from the layer (A), or a two-layer sheet which contains the layer (A) and the layer (B), and from the viewpoint of achieving both transparency and adhesiveness, the three-layer sheet is preferable.

In the present invention, it is preferable that the layer (A) is thinner than the layer (B), from the viewpoint of transparency. Specifically, the thickness a of the layer (A) is preferably in a range of from 1 μm to 500 μm. Above all, the thickness a is preferably in a range of from 10 μm to 500 μm, and more preferably in a range of from 20 μm to 300 μm. When the thickness a is 1 μm or more, the adhesive strength can be maintained, and when the thickness a is 500 μm or less, excellent transparency may be realized.

Further, in view of transparency, the thickness of the layer (B) based on the total layer thickness may be high. Specifically, when the multilayer material of the present invention is used as an encapsulant of a solar cell, the thickness b of the layer (B) is preferably in a range of from 100 μm to 2000 μm, and more preferably in a range of from 150 μm to 1500 μm. When the thickness b is 100 μm or more, it is possible to obtain a higher transparency than heretofore, and when the thickness is 1500 μm or less, it is advantageous in terms of flexibility. Further, when the multilayer material of the present invention is used as an interlayer of safety (laminated) glass, the thickness b of the layer (B) can be freely set within the range obtained by subtracting the above thickness of the layer (A) from the preferable total thickness in a range of from 5 μm to 2000 μm.

The ratio (a/b) of the layer thicknesses of the layer (A) (thickness a) and the layer (B) (thickness b), which constitute the multilayer material, is preferably from 1/1 to 1/20, more preferably from 1/1 to 1/10, and even more preferably from 1/1 to 1/8. When the ratio (a/b) of the thickness a of the layer (A) to the thickness b of the layer (B) is within the above range, more excellent adhesiveness and transparency may be achieved. Specifically, when the multilayer material is used in a solar cell, an encapsulant for a solar cell which has excellent adhesiveness and excellent transparency and which can be suitably used in a solar cell module may be obtained. When the multilayer material is used as an interlayer for safety (laminated) glass, an interlayer for safety (laminated) glass which has excellent adhesiveness and excellent transparency and which can be suitably used in safety (laminated) glass may be obtained.

The multilayer material of the present invention may be molded by a known method using a monolayer or multilayer T-die extruder, a calender molding machine, a monolayer or multilayer inflation molding machine, or the like. For example, to each of the ethylene type Zn ionomer, the ethylene type Na ionomer, and the ethylene type Mg ionomer, additives such as an adhesion enhancing agent, an antioxidant, a light stabilizer, or an ultraviolet absorbent are added as necessary, followed by dry blending and by supplying the resulting mixture from the hopper of a main extruder or a sub-extruder of a multilayer T-die extruder to perform multilayer extrusion molding into a sheet shape, the multilayer material of the invention may be obtained.

The multilayer material of the present invention can realize a light transmission in accordance with JIS-K 7105 of 88% or higher, when this multilayer material (for example, an encapsulant for a solar cell or an interlayer for safety (laminated) glass) is subjected to pasting in the state of being interposed between two sheets of float glass having a thickness of 3.2 mm, by using a double vacuum chamber pasting apparatus (conditions: at 150° C. for 8 minutes), and cooling (namely, slow cooling) in the ambient air of 23° C. That is, in general, there is a tendency that the transparency is deteriorated when cooled slowly after pasting, and therefore, usually, rapid cooling is performed after pasting and evaluation of the light transmission after rapid cooling is carried out; however, in the present invention, an extremely excellent transparency is exhibited such that the light transmission after slow cooling is 88% or higher.

Further, it is more preferable that the light transmission is 90% or higher.

The light transmission is a value measured in accordance with JIS-K 7105 by using a haze meter (manufactured by Suga Test Instruments Co., Ltd.). The term “cooling (slow cooling)” means that cooling is performed at a cooling speed of 15° C./min or less (calculated from the temperature after 5 minutes from the initiation of cooling).

In the case of utilizing the multilayer material of the invention for application to a solar cell, the multilayer material of the invention is suitably used as an use application (a so-called encapsulant) for encapsulating amorphous silicone solar cell elements.

[Solar Cell Module]

The solar cell module of the present invention is produced by fixing the upper part and the lower part of a solar cell element with a protection material. The solar cell module of the present invention is provided with the above-described multilayer material of the present invention as an encapsulant for a solar cell. Examples of the solar cell module of the present invention include (a) the one having a constitution in which a solar cell element is sandwiched by the encapsulants for solar cells (multilayer sheets) from the two sides of the solar cell element, such as a laminate structure of upper transparent protection material arranged on the side on which sunlight is incident/encapsulant for solar cell (multilayer sheet)/solar cell element/encapsulant for solar cell (multilayer sheet)/lower protection material that protects the rear face on the side opposite to the side on which sunlight is incident; and (b) the one having a constitution in which an encapsulant for a solar cell (multilayer sheet) and a lower protection material are formed in this order on the element formed-face of an upper transparent protection material which a solar cell element was formed on one surface of the upper transparent protection material, for example, a substance prepared by providing an amorphous solar cell element on glass or a fluorocarbon resin sheet by sputtering or the like.

The encapsulant for a solar cell of the present invention which constitutes the solar cell module may include only the above-described multilayer sheet according to the present invention, or may include this multilayer sheet and other sheet or other material.

In such a solar cell module, when the encapsulant for a solar cell of the present invention has a three-layer structure of layer (A)/layer (B)/layer (A), one of the layer (A), which is an outer layer, is disposed so as to be in contact with the solar cell element, and the other layer (A), that is another outer layer, is laminated so as to be in contact with the upper transparent protection material or the lower protection material. Further, when the encapsulant for a solar cell of the present invention has a two-layer structure of layer (A)/layer (B), it is preferable that the layer (B) is provided so as to be in contact with the solar cell element, and the layer (A) is laminated so as to be in contact with the upper transparent protection material or the lower protection material (back sheet).

Since the layer (A) and the layer (B) are each formed by using an ionomer, the encapsulant for a solar cell of the present invention has excellent moisture resistance. Generally, the solar cells tend to have poor resistance to moisture, since thin film type solar cells use an electrode of a metal membrane formed on a substrate by deposition. From this point of view, the form in which the encapsulant for a solar cell of the present invention is used in a thin film type solar cell is one of preferable embodiments. Specifically, it is one of preferable embodiment that the encapsulant for a solar cell of the present invention is applied to a thin film type solar cell having a constitution in which an encapsulant for a solar cell and a lower protection material are provided on a solar cell element which is formed on the inner spherical surface of an upper protection material having transparency.

As the solar cell element, solar cell elements, for example, Group IV semiconductors such as single crystal silicon, polycrystalline silicon, or amorphous silicon; Group III-V and Group II-VI compound-type semiconductors such as gallium-arsenic, copper-indium-selenium, copper-indium-gallium-selenium, or cadmium-tellurium; and the like may be used.

[Safety (Laminated) Glass]

The safety (laminated) glass of the present invention is constituted by fixing two glass sheets with the interlayer for the safety (laminated) glass described above.

The safety (laminated) glass of the present invention is provided with the above-described multilayer material of the present invention as the interlayer. An example of the safety (laminated) glass of the present invention is safety (laminated) glass having a constitution in which a laminate structure of glass sheet/interlayer for safety (laminated) glass sheet (multilayer sheet)/glass sheet is formed.

More specifically, a constitution in which a laminate structure of glass sheet/ethylene type zinc ionomer layer containing a silane coupling agent/ethylene-based sodium or magnesium ionomer layer that does not contain a silane coupling agent/ethylene type zinc ionomer layer containing a silane coupling agent/glass sheet is formed; a constitution in which a laminate structure of glass sheet/ethylene type zinc ionomer layer containing a silane coupling agent/ethylene-based sodium or magnesium ionomer layer that contains a silane coupling agent/ethylene type zinc ionomer layer containing a silane coupling agent/glass sheet is formed; and the like are described. Further, constitutions in which, in the above constitutions, a colorant is compounded to at least one of the ethylene type zinc ionomer layer or the ethylene type sodium or magnesium ionomer layer, and the like are described.

The material of the glass sheet is not particularly limited, and soda-lime glass is preferably used. Above all, high permeability glass (so-called non-ion (iron free) tempered glass) is preferably used. High permeability glass is soda lime glass which has a low iron content and has a high light transmission. Further, figured glass with an embossed pattern formed on a surface thereof is also preferably used. Moreover, when the glass sheet is used as a rear face protection material, soda lime glass having a high iron content (so-called float glass), IR reflecting glass, heat absorbing glass, or the like can also be used preferably.

When the glass sheet is a plate-like glass material, the thickness of the glass sheet is not particularly limited, but generally, the thickness is preferably 4 mm or less, and more preferably 2.5 mm or less. The lower limit of the thickness is not limited, but generally, the lower limit is preferably 0.1 mm, and more preferably 0.5 mm.

In order to produce the safety (laminated) glass of the present invention, for example, an interlayer may be placed between two glass sheets, followed by thermocompression bonding under heat and pressure. The heating temperature is, for example, from about 100° C. to about 250° C., and the pressure is, for example, from about 0.1 kg/cm² to about 30 kg/cm².

### EXAMPLES

Hereinafter, the invention will be more specifically explained based on Examples, but the invention is not intended to be limited to the following Examples as long as the gist is maintained. Unless particularly stated otherwise, the term “part” is based on mass.

The terms “ethylene content”, “methacylic acid content”, and “isobutyl acrylate content” respectively represent the ratio of the constituent unit derived from ethylene, methacrylic acid, or butyl acrylate, in the resin.

The materials used in Examples and Comparative Examples described below, compounding of the respective layers, the base material, and evaluation methods are as follows.

—(1) Resin—

### 1. Resin Materials for Layer (A)

Ionomer 1: a zinc ionomer (neutralization degree 23%, MFR 11 g/10 min, melting point 94° C.) of an ethylene-methacrylic acid copolymer (ethylene content=85% by mass, methacrylic acid content=15% by mass)

Ionomer 2: a zinc ionomer (neutralization degree 12%, MFR 11 g/10 min, melting point 94° C.) of an ethylene-methacrylic acid copolymer (ethylene content=85% by mass, methacrylic acid content=15% by mass)

### 2. Resin Materials for Layer (B)

Ionomer 3: a magnesium ionomer of an ethylene-methacrylic acid copolymer (ethylene content=85% by mass, methacrylic acid content=15% by mass, neutralization degree 40%, MFR 5 g/10 min, melting point 93° C.)

Ionomer 4: a magnesium ionomer of an ethylene-methacrylic acid copolymer (ethylene content=85% by mass, methacrylic acid content=15% by mass, neutralization degree 54%, MFR 5 g/10 min, melting point 92° C.)

Ionomer 5: a sodium ionomer of an ethylene-methacrylic acid copolymer (ethylene content=81% by mass, methacrylic acid content=19% by mass, neutralization degree 45%, MFR 4.5 g/10 min, melting point 87° C.)

—(2) Additives—

Antioxidant: IRGANOX 1010 (trade name, manufactured by Ciba Specialty Chemicals K.K. Japan, currently BASF Japan Ltd.)

Ultraviolet absorbent-1: 2-hydroxy-4-n-octoxybenzophenone

Ultraviolet absorbent-2: 2-(2H-benzotriazol-2-yl)-4,6-di-t-pentylphenol

Light stabilizer: bis(2,2,6,6-tetramethyl-4-piperidyl) sebacate

Silane coupling agent: N-(2-aminoethyl)-3-aminopropylmethyldimethoxysilane

The ultraviolet absorbent, the light stabilizer, and the antioxidant were used by preparing masterbatches in advance together with the same resin as the resin incorporated in the layer, in the following ratios (mass ratio), by means of a twin screw extruder.

Additive Masterbatch (1):

ionomer 1/ultraviolet absorbent-1/light stabilizer/antioxidant=95.2/3/1.5/0.3

Additive Masterbatch (2):

ionomer 3/ultraviolet absorbent-2/light stabilizer/antioxidant=95.2/3/1.5/0.3

Additive Masterbatch (3):

ionomer 5/ultraviolet absorbent-1/light stabilizer/antioxidant=95.2/3/1.5/0.3

—(3) Compounding—

Compounding of the layers to be formed was carried out by mixing in advance in the following mixing ratios. In the case of compounding a silane coupling agent, mixing was carried out using a polyethylene bag and stirring was carried out for 30 minutes or more, using a tumbler.

### <Layer (A)>

(A)-1: ionomer 1/additive masterbatch (1)/silane coupling agent=90/10/0.2

(A)-2: ionomer 2/additive masterbatch (1)/silane coupling agent=90/10/0.2

(A)-3: ionomer 2/additive masterbatch (1)=90/10

### <Layer (B)>

(B)-1: ionomer 3/additive masterbatch (2)=90/10

(B)-2: ionomer 4/additive masterbatch (2)=90/10

(B)-3: ionomer 5/additive masterbatch (3)=90/10

(B)-4: ionomer 4/additive masterbatch (2)/silane coupling agent=90/10/0.2

(B)-5: ionomer 5/additive masterbatch (3)/silane coupling agent=90/10/0.2

—(4) Base Material—

Tempered float glass having a thickness of 3.2 mm (manufactured by ASAHI GLASS CO., LTD.)

—(5) Methods of Evaluation—

Methods of evaluation with regard to the multilayer sheets and monolayer sheets prepared in Examples and Comparative Examples described below are shown below. Note that, the multilayer sheets and monolayer sheets thus prepared were sheets that were assumed to be used as an encapsulant for a photovoltalic (solar) cell or an interlayer for safety (laminated) glass (safety glass interlayer). Further, with regard to the application for a solar cell, the evaluation method is a substitute test assuming that the solar cell element is provided on the sheet adhered-surface of glass.

i) Adhesive Strength

Using tempered float glass having a thickness of 3.2 mm (75 mm×120 mm) and a multilayer sheet or monolayer sheet having a thickness of 0.4 mm, a sample having a constitution including a laminate structure of tempered float glass/multilayer sheet (or monolayer sheet) was prepared by using a vacuum heat pasting device (trade name: LM-50×50S, manufactured by NPC Corporation; a double vacuum chamber pasting apparatus) under the condition of 150° C. for 8 minutes. Using this sample, the adhesive strength between the tempered float glass and the multilayer sheet (or the monolayer sheet) was measured. The measurement was conducted under the conditions of 15 mm in width and at a tensile speed of 100 mm/min.

Further, the sample after measurement was subjected to aging under an environment of 85° C. and 90% RH for 1000 hours, and also with regard to the sample after aging, measurement of adhesive strength was carried out in substantially the same manner.

ii) Transparency

Tempered float glass having a thickness of 3.2 mm (75 mm×120 mm) and a multilayer sheet or monolayer sheet having a thickness of 0.4 mm were used and laminated using a vacuum heat pasting device (trade name: LM-50×50S, manufactured by NPC Corporation; a double vacuum chamber pasting apparatus) under the condition of 150° C. for 8 minutes. Thereafter, in the state in which one end of the narrower side of the resultant was fixed and in which the resultant was stood on a glass stand, the resultant was left and slowly cooled (cooling speed=13° C./min, the surface temperature of the center of the glass after 5 minutes from the initiation of cooling was 85° C.) in the ambient air having a temperature of 23° C., to prepare a sample having a constitution including a laminate structure of tempered float glass/multilayer sheet (or monolayer sheet)/tempered float glass. Using this sample, the light transmission was measured in accordance with JIS-K 7105 by using a haze meter (manufactured by Suga Test Instruments Co., Ltd.). Further, the spectral distribution was measured using UV2550 (trade name, manufactured by Shimadzu Corporation), the transmission at 500 nm was measured.

The evaluation was carried out by setting the thickness of the multilayer sheet to 400 μm or 800 Regarding the multilayer sheet having the thickness of 800 μm, a safety (laminated) glass in which the multilayer sheet had a thickness of 800 μm was prepared by interposing two multilayer sheets described above between two sheets of glass, and the resultant was evaluated according to the above methods.
—(6) Molding of Multilayer Sheet—

Multilayer sheets were prepared using the following molding machine at a processing temperature of 160° C. All of the following molding machines are 40 mm φ of single screw extruders with a die width of 500 mm.

3-Type 3-layer multilayer casting mold machine (3-layer multilayer of three resins): manufactured by TANABE PLASTICS MACHINERY CO., LTD.

Co-extrusion feed block: manufactured by EDI

### Example 1

Using (A)-1 for an outer layer and (B)-1 for an intermediate layer, a multilayer sheet having a thickness ratio (outer layer 1/intermediate layer/outer layer 2)=1/2/1 and a total thickness of 400 μm (0.4 mm) was prepared, by means of a multilayer casting mold machine at a resin temperature of 160° C. Using this multilayer sheet, various evaluations described above were carried out. Results are shown in Table 1 below.

### Example 2

A multilayer sheet was prepared in a manner substantially similar to that in Example 1 except that the thickness ratio in Example 1 was changed to a thickness ratio of outer layer 1/intermediate layer/outer layer 2=1/4/1 (total thickness=0.4 mm), and the evaluations thereof were carried out. Results are shown in Table 1 below.

### Example 3

A multilayer sheet was prepared in a manner substantially similar to that in Example 1 except that the thickness ratio in Example 1 was changed to a thickness ratio of outer layer 1/intermediate layer/outer layer 2=1/6/1 (total thickness=0.4 mm), and the evaluations thereof were carried out. Results are shown in Table 1 below.

### Example 4

A multilayer sheet was prepared in a manner substantially similar to that in Example 1 except that the (A)-1 used for the outer layer in Example 1 was replaced by (A)-2, and the evaluations thereof were carried out. Results are shown in Table 1 below.

### Example 5

A multilayer sheet was prepared in a manner substantially similar to that in Example 1 except that the (B)-1 used for the intermediate layer in Example 1 was replaced by (B)-2, and the evaluations thereof were carried out. Results are shown in Table 1 below.

### Example 6

A multilayer sheet was prepared in a manner substantially similar to that in Example 5 except that the thickness ratio in Example 5 was changed to a thickness ratio of outer layer 1/intermediate layer/outer layer 2=1/4/1 (total thickness=0.4 mm), and the evaluations thereof were carried out. Results are shown in Table 1 below.

### Example 7

A multilayer sheet was prepared in a manner substantially similar to that in Example 5 except that the thickness ratio in Example 5 was changed to a thickness ratio of outer layer 1/intermediate layer/outer layer 2=1/6/1 (total thickness=0.4 mm), and the evaluations thereof were carried out. Results are shown in Table 1 below.

### Example 8

A multilayer sheet was prepared in a manner substantially similar to that in Example 1 except that (A)-1 used for the outer layer in Example 1 was replaced by (A)-2, and the (B)-1 used for the intermediate layer in Example 1 was replaced by (B)-3, and then, the evaluations thereof were carried out. Results are shown in Table 1 below.

### Comparative Example 1

Various evaluations described above were carried out in a manner substantially similar to that in Example 1 except that the (B)-1 that formed the intermediate layer in Example 1 was not used and a monolayer sheet of (A)-1 alone was prepared. Results are shown in Table 2 below.

### Comparative Example 2

A multilayer sheet was prepared in a manner substantially similar to that in Example 1, except that the (A)-1 used for the outer layer in Example 1 was replaced by (A)-3, which did not contain a silane coupling agent, and the evaluations thereof were carried out. Results are shown in Table 2 below.

### Comparative Examples 3 to 6

Various evaluations described above were carried out in a manner substantially similar to that in Example 1, except that the (A)-1 which was used for forming the outer layer in Example 1 was not used and monolayer sheets of (B)-2, (B)-3, (B)-4, or (B)-5 alone were prepared. Results are shown in Table 2 below.

TABLE 1

| | | | | | | | Transparency | | Adhesiveness | |
|---|---|---|---|---|---|---|---|---|---|---|
| | | | | | Light Transmission | | - Transmission [%] - | | (N/15 mm | |
| | | | | | [%] | | (at 500 nm) | | Average Strength) | |
| | | | | | Sheet | Sheet | Sheet | Sheet | | After |
| | Laminated | Outer | Intermediate | Thickness | Thickness | Thickness | Thickness | Thickness | Before | Aging |
| | Structure | Layer (A) | Layer (B) | Ratio A/B | 400 μm | 800 μm | 400 μm | 800 μm | Aging | (1000 hr) |
| Example 1 | A/B/A | (A)-1 | (B)-1 | 1/1 | 90.3 | — | 88.7 | — | 49 | 42 |
| Example 2 | A/B/A | (A)-1 | (B)-1 | 1/2 | 90.5 | — | 89.5 | — | 48 | 44 |
| Example 3 | A/B/A | (A)-1 | (B)-1 | 1/3 | 90.6 | 90.0 | 89.6 | 88.0 | 46 | 40 |
| Example 4 | A/B/A | (A)-2 | (B)-1 | 1/1 | 89.7 | — | 88.2 | — | 52 | 44 |
| Example 5 | A/B/A | (A)-1 | (B)-2 | 1/1 | 90.5 | — | 89.4 | — | 52 | 46 |
| Example 6 | A/B/A | (A)-1 | (B)-2 | 1/2 | 90.6 | — | 90 | — | 51 | 42 |
| Example 7 | A/B/A | (A)-1 | (B)-2 | 1/3 | 90.7 | 90.3 | 90.2 | 89.3 | 50 | 40 |
| Example 8 | A/B/A | (A)-2 | (B)-3 | 1/1 | 89.9 | — | 88.4 | — | 52 | 38 |

TABLE 2

| | | | | | | | Transparency | | Adhesiveness | |
|---|---|---|---|---|---|---|---|---|---|---|
| | | | | | Light Transmission | | - Transmission [%] - | | (N/15 mm | |
| | | | | | [%] | | (at 500 nm) | | Average Strength) | |
| | | | | | Sheet | Sheet | Sheet | Sheet | | After |
| | Laminated | Outer | Intermediate | Thickness | Thickness | Thickness | Thickness | Thickness | Before | Aging |
| | Structure | Layer (A) | Layer (B) | Ratio A/B | 400 μm | 800 μm | 400 μm | 800 μm | Aging | (1000 hr) |
| Comparative | — | (A)-1 monolayer | | — | 89.1 | 86.8 | 87.2 | 82.9 | 49 | 42 |
| Example 1 | | | | | | | | | | |
| Comparative | A/B/A | (A)-3 | (B)-1 | 1/1 | 88.3 | — | 85.3 | — | 48 | impossible to |
| Example 2 | | | | | | | | | | measure due |
| | | | | | | | | | | to peeling |

| | | | | | | | | | |
|---|---|---|---|---|---|---|---|---|---|
| Comparative | — | (B)-2 monolayer | — | 90.6 | — | 90.8 | — | 12 | impossible to |
| Example 3 | | | | | | | | | measure due |
| | | | | | | | | | to peeling |
| Comparative | — | (B)-4 monolayer | — | impossible to | — | — | — | — | — |
| Example 4 | | | | prepare, since | | | | | |
| | | | | gelation | | | | | |
| | | | | occurred | | | | | |
| | | | | during | | | | | |
| | | | | processing | | | | | |
| Comparative | — | (B)-3 monolayer | — | 90.6 | — | 90.4 | — | 20 | impossible to |
| Example 5 | | | | | | | | | measure due |
| | | | | | | | | | to peeling |
| Comparative | — | (B)-5 monolayer | — | impossible to | — | — | — | — | — |
| Example 6 | | | | prepare, since | | | | | |
| | | | | gelation | | | | | |
| | | | | occurred | | | | | |
| | | | | during | | | | | |
| | | | | processing | | | | | |

As shown in Table 1 and Table 2 above, the Examples exhibited excellent adhesiveness, while maintaining a higher transparency, as compared with the Comparative Examples.

The entire disclosure of Japanese Patent Application No. 2010-111366 and Japanese Patent Application No. 2010-209356 have been incorporated in this specification by reference.

All documents, patent applications and technical specifications recited in this specification are incorporated herein by reference in this specification to the same extent as if each individual publication, patent applications and technical standard was specifically and individually indicated to be incorporated by reference.

1. A multilayer material, comprising:
a layer (A) comprising a silane coupling agent and an ethylene type zinc ionomer; and
a layer (B) comprising at least one of an ethylene type magnesium ionomer or an ethylene type sodium ionomer.

2. The multilayer material according to claim 1, having at least two of the layer (A) and at least one of the layer (B), and comprising a multilayered structure in which one of the layer (B) is interposed between two of the layer (A).

3. The multilayer material according to claim 1, wherein, in the layer (B), a content ratio of a silane coupling agent is 0.1% by mass or lower relative to a solid content of the layer (B).

4. The multilayer material according to claim 1, wherein the layer (A) contains dialkoxysilane having an amino group in an amount of 3 parts by mass or less relative to 100 parts by mass of the ethylene type zinc ionomer.

5. The multilayer material according to claim 1, wherein the total thickness of the thickness of the layer (A) and the thickness of the layer (B) is from 0.1 mm to 2 mm.

6. The multilayer material according to claim 1, wherein a ratio (a/b) of a thickness a of the layer (A) to a thickness b of the layer (B) is from 1/1 to 1/20.

7. The multilayer material according to claim 1, wherein the melt flow rates (MFR; JIS K 7210-1999, at 190° C., under a load of 2160 g) of the ethylene type zinc ionomer in the layer (A) and the at least one of the ethylene type magnesium ionomer or the ethylene type sodium ionomer in the layer (B) are respectively from 0.1 g/10 min to 150 g/10 min.

8. The multilayer material according to claim 1, wherein the melt flow rate of the ethylene type zinc ionomer in the layer (A) (MFR; JIS K 7210-1999, at 190° C., under a load of 2160 g) is higher than the melt flow rate of the at least one of the ethylene type magnesium ionomer or the ethylene type sodium ionomer in the layer (B).

9. The multilayer material according to claim 1, having a light transmission in accordance with JIS-K 7105 of 88% or higher, when subjected to pasting in a state of being interposed between two sheets of float glass each having a thickness of 3.2 mm, using a double vacuum chamber pasting apparatus under conditions of 150° C. for 8 minutes, followed by cooling in ambient air at 23° C.

10. The multilayer material according to claim 1, wherein at least one of the layer (A) or the layer (B) further contains one or more additives selected from the group consisting of ultraviolet absorbents, light stabilizers, and antioxidants.

11. The multilayer material according to claim 1, wherein the ethylene type zinc ionomer comprises an ionomer of an ethylene-acrylic acid copolymer or an ethylene-methacrylic acid copolymer, and the at least one of the ethylene type magnesium ionomer or the ethylene type sodium ionomer comprises an ionomer of an ethylene-acrylic acid copolymer or an ethylene-methacrylic acid copolymer.

12. The multilayer material according to claim 1, wherein a content ratio of the ethylene type zinc ionomer in the layer (A) is 60% by mass or more relative to a total mass of the layer (A), and a content ratio of a total amount of the ethylene type magnesium ionomer and the ethylene type sodium ionomer in the layer (B) is 60% by mass or more relative to a total mass of the layer (B).

13. The multilayer material according to claim 1, wherein a content ratio of the ethylene type magnesium ionomer in the layer (B) is 80% by mass or higher relative to a total amount of a resin material including the ionomers.

14. An encapsulant for a solar cell, comprising the multilayer material according to claim 1.

15. An interlayer for safety (laminated) glass, comprising the multilayer material according to claim 1.

16. A solar cell module, comprising the multilayer material according to claim 1, as an encapsulant for a solar cell.

17. Safety (laminated) glass, comprising the multilayer material according to claim 1, as an interlayer for safety glass (laminated) glass.
